(19) United States
(12) Patent Application Publication
(10) Pub. No.: US 2021/0232046 A1
(43) Pub. Date: Jul. 29, 2021

(54) DEVELOPING DEVICE AND DEVELOPING METHOD

(71) Applicant: WUHAN CHINA STAR OPTOELECTRONICS TECHNOLOGY CO., LTD., Wuhan, Hubei (CN)

(72) Inventors: Wei LI, Wuhan, Hubei (CN); Zhenyu ZHAO, Wuhan, Hubei (CN)

(21) Appl. No.: 16/307,313

(22) PCT Filed: Aug. 27, 2018
(86) PCT No.: PCT/CN2018/102409

§ 371 Date: Dec. 5, 2018

(30) Foreign Application Priority Data
Apr. 28, 2018 (CN) 201810399857.3

(51) Int. Cl. G03F 7/00; B05B 13/02; G03F 7/30

(52) U.S. Cl. CPC G03F 7/0025; B05B 13/0221; G03F 7/30; B05B 13/0278

(57) ABSTRACT

A developing device and a developing method are provided. The developing device includes a developing chamber, a conveyor table, and an air ejection member. A spraying member in the developing chamber sprays a developing agent onto a surface of a display device. The conveyor table moves the display device from outside of the developing chamber to inside of the developing chamber, and from inside of the developing chamber to outside of the developing chamber. The air ejection member ejects airflow onto the display device. The developing agent disposed on the display device can be prevented from flowing out of the developing chamber.

### FIELD OF INVENTION

The present disclosure relates to a manufacturing technology field of display devices, and more particularly to a developing device and a developing method.

### BACKGROUND OF INVENTION

A conventional developing device is used for a develop process of display devices, and the developing process is that:

After being exposed, the display device which is coated with photoresist is moved to a developing chamber for the developing device by rollers. A nozzle of a developing agent in the developing chamber is opened, and the developing agent is evenly sprayed onto the display device, and the developing agent fully reacts with the photoresist on the surface of the display device, so as to form a pattern. The remaining developing agent flows into a developing recycle tank along the display device, and then returns to a developing storage tank through a drain pipe to be recycled.

However, when the display device is moved from outside of the developing chamber to inside of the developing chamber, a portion of the display device is outside of the developing chamber, and the other portion of the display device is inside of the developing chamber.

When the display device moves forward with rotation of the rollers, because of inertia, the developing agent sprayed on the display device by the developing agent nozzle does not immediately move at the same speed with the display device, but is influenced by inertia to move in a direction opposite to the moving direction of the display device. Therefore, a portion of the developing agent flows out of the developing chamber and cannot flow into the developing chamber to be recycled. At the same time, the developing agent remaining in the outside of the developing chamber contains a high concentration of photoresist, and after a long time, this portion of the photoresist will evaporate to produce a photoresist residue, which will seriously affect quality of subsequent products.

Hence, it is necessary to provide a new technical solution to solve the above-mentioned technical problems.

### SUMMARY OF INVENTION

An object of the present disclosure is to provide a developing device and a developing method, which can prevent a developing agent disposed on a display device from flowing out of the developing chamber.

In order to solve the above-mentioned problems, a technical solution of the present disclosure is as follows:

A developing device, which comprises: a developing chamber configured to carry out a developing process to a display device therein, wherein a spraying member is disposed in the developing chamber, and is configured to spray a developing agent onto a surface of at least one portion of the display device in the developing chamber; a conveyor table, wherein at least one portion of the conveyor table is disposed inside the developing chamber, and the conveyor table is configured to move the display device waiting to be processed by the developing process from outside of the developing chamber to inside of the developing chamber, and configured to move the display device being processed by the developing process from inside of the developing chamber to outside of the developing chamber; and an air ejection member configured to eject airflow onto the display device when the display device is moved from outside of the developing chamber to inside of the developing chamber, so as to prevent the developing agent disposed on a portion of the display device within the developing chamber from flowing out of the developing chamber; wherein the conveyor table at least comprises a first sub-table and a second sub-table; wherein the developing device further comprises a lifter disposed between the first sub-table and the second sub-table; wherein the lifter comprises a movable plate and a lifting column, wherein a first side of the movable plate is hinged with the first sub-table, and a second side of the movable plate is connected with the lifting column; wherein the spraying member is disposed on an inner surface of a top portion or a side wall of the developing chamber; the spraying member is connected with a developing agent delivering pipe, and the developing agent delivering pipe is connected with a developing agent supply tank and/or a developing agent recycle member disposed in the development chamber; and wherein the air ejection member is disposed inside of the developing chamber, and an ejection direction of the airflow ejected by the air ejection member is perpendicular to the surface of the display device.

In the above-mentioned developing device, the air ejection member is disposed at an entrance of the developing chamber, and the air ejection member is fixed on the inner surface of the top portion or the side wall of the developing chamber.

A developing device, which comprises: a developing chamber configured to carry out a developing process to a display device therein, wherein a spraying member is disposed in the developing chamber, and is configured to spray a developing agent onto a surface of at least one portion of the display device in the developing chamber; a conveyor table, wherein at least one portion of the conveyor table is disposed inside the developing chamber, and the conveyor table is configured to move the display device waiting to be processed by the developing process from outside of the developing chamber to inside of the developing chamber, and configured to move the display device being processed by the developing process from inside of the developing chamber to outside of the developing chamber; and an air ejection member configured to eject airflow onto the display device when the display device is moved from outside of the developing chamber to inside of the developing chamber, so as to prevent the developing agent disposed on a portion of the display device within the developing chamber from flowing out of the developing chamber.

In the above-mentioned developing device, the air ejection member comprises a first pipe and a nozzle; the first pipe is connected with the nozzle; and the first pipe is configured to move the airflow, and to output the airflow through the nozzle.

In the above-mentioned developing device, the air ejection member further comprises a second pipe and a third pipe; the second pipe and the third pipe are both connected with the nozzle; the second pipe is configured to deliver water, and to output the water through the nozzle; and the third pipe is configured to deliver a cleaning liquid, and to output the cleaning liquid through the nozzle.

In the above-mentioned developing device, the developing device further comprises: a lifter configured to control at least one portion of the display device up or down, so that the developing agent disposed on the display device flows toward a predetermined direction.

In the above-mentioned developing device, the lifter is configured to control the display device being inclined at a predetermined angle toward a delivering direction of the conveyor table, so that the developing agent disposed on the display device flows toward the predetermined direction; and the predetermined angle ranges from 1 to 20 degrees.

In the above-mentioned developing device, the conveyor table at least comprises a first sub-table and a second sub-table; the lifter is disposed between the first sub-table and the second sub-table; and the lifter comprises a movable plate and a lifting column, wherein a first side of the movable plate is hinged with the first sub-table, and a second side of the movable plate is connected with the lifting column.

In the above-mentioned developing device, the air ejection member is disposed inside of the developing chamber.

In the above-mentioned developing device, the air ejection member is disposed at an entrance of the developing chamber, and the air ejection member is fixed on an inner surface of a top portion or a side wall of the developing chamber.

In the above-mentioned developing device, an ejection direction of the airflow ejected by the air ejection member is perpendicular to the surface of the display device, or the ejection direction has a first predetermined angle with the surface of the display device.

In the above-mentioned developing device, the spraying member is disposed on an inner surface of a top portion or a side wall of the developing chamber; the spraying member is connected with a developing agent delivering pipe, and the developing agent delivering pipe is connected with a developing agent supply tank and/or a developing agent recycle member disposed in the development chamber.

A developing method, which comprises: a step A of using a conveyor table to move a display device waiting to be processed by a developing process from outside of a developing chamber to inside of the developing chamber; a step B of using a spraying member disposed in the developing chamber to spray a developing agent onto a surface of at least one portion of the display device within the developing chamber; a step C of using an air ejection member to eject airflow onto the display device when the display device is moved from outside of the developing chamber to inside of the developing chamber, so as to prevent the developing agent disposed on the portion of the display device within the developing chamber from flowing out of the developing chamber; and a step D of using the developing chamber to carry out the developing process to the display device after the display device enters the developing chamber.

In the above-mentioned developing method, after the step B, the method further comprises: a step E of using a lifter to control at least one portion of the display device up or down, so that the developing agent disposed on the display device flows toward a predetermined direction.

In the above-mentioned developing method, in the step E, the lifter controls the display device is inclined at a predetermined angle toward a delivering direction of the conveyor table, so that the developing agent disposed on the display device flows toward the predetermined direction; and the predetermined angle ranges from 1 to 20 degrees.

In the above-mentioned developing method, the conveyor table at least comprises a first sub-table and a second sub-table; and the lifter comprises a movable plate and a lifting column, wherein a first side of the movable plate is hinged with the first sub-table, and a second side of the movable plate is connected with the lifting column; and wherein the step E comprises: using the lifting column to control the second side of the movable plate up or down, so as to control the display device moved on the lifter being inclined at the predetermined angle toward the delivering direction of the conveyor table, so that the developing agent disposed on the display device flows toward the predetermined direction.

In the above-mentioned developing method, the method further comprises: a step F of using the conveyor table to move the display device being processed by the developing process from inside of the developing chamber to outside of the developing chamber.

In the above-mentioned developing method, an ejection direction of the airflow ejected by the air ejection member is perpendicular to the surface of the display device, or the ejection direction has a first predetermined angle with the surface of the display device.

In the above-mentioned developing method, before the step B, the developing method further comprises: a step G of using a developing agent delivering pipe to deliver the developing agent, so as to supply the developing agent to the spraying member; wherein the developing agent delivering pipe is connected with a developing agent supply tank and/or a developing agent recycle member disposed in the development chamber.

In the above-mentioned developing method, the step A comprises: using the conveyor table to move the display device waiting to be processed by the developing process from outside of the developing chamber to inside of the developing chamber at a constant speed, or to move the display device waiting to be processed by the developing process from outside of the developing chamber to inside of the developing chamber at a changeable speed.

In the present disclosure, the air ejection member intercepts the developing agent by the airflow from the portion of the display device inside of the developing chamber flowing toward the portion of the display device outside of the developing chamber, so that the present disclosure can prevent that the developing agent from flowing out of the developing chamber.

In order to make the above contents of the present disclosure more comprehensible, several embodiments of the present disclosure, the following preferred embodiment and the accompanying drawings, described in detail below.

### DESCRIPTION OF DRAWINGS

FIG. 1 is a schematic view of a first embodiment of a developing device of the present disclosure.

FIG. 2 is a schematic view of a second embodiment of the developing device of the present disclosure.

FIG. 3 is a schematic view of a third embodiment of the developing device of the present disclosure.

FIG. 4 is a flowchart of the developing method of the present disclosure.

### DETAILED DESCRIPTION OF PREFERRED EMBODIMENTS

Words used in this specification to “an embodiment” mean serving as an example, instance, or illustration. Further, in this specification and the appended claims used in the articles “a” may generally be construed to mean “one or more” unless specified otherwise or clear from the context to determine a singular form.

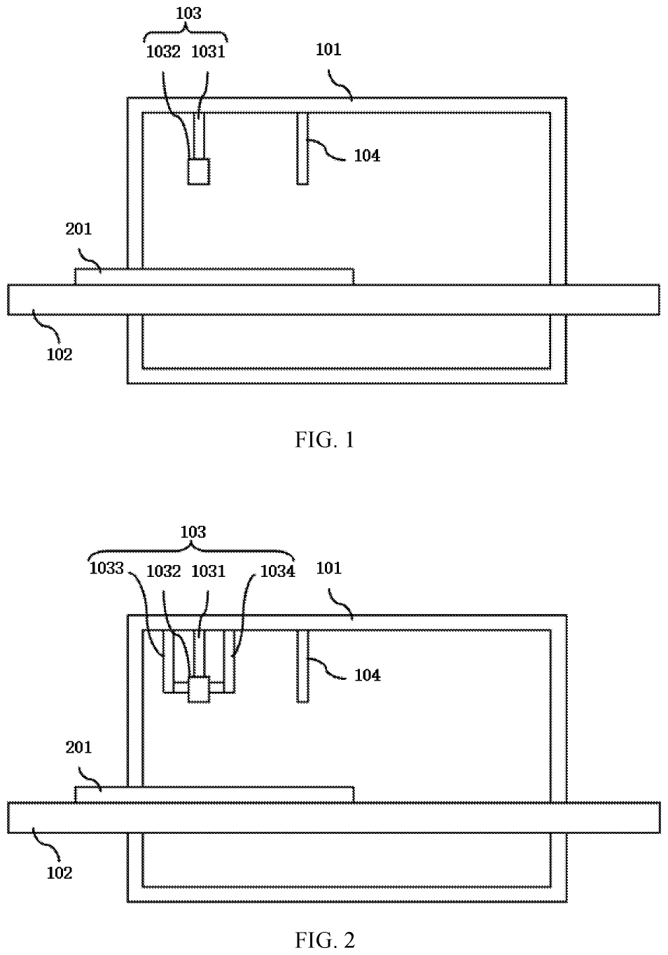

Refer to FIG. 1, which is a schematic view of a first embodiment of a developing device of the present disclosure.

A developing device of the present disclosure includes a developing chamber 101, a conveyor table 102, and an air ejection member 103.

The developing chamber 101 is configured to carry out a developing process to a display device 201 located in the developing chamber 101. The developing chamber 101 is provided with a spraying member 104, and the spraying member 104 is configured to spray a developing agent onto a surface of at least one portion of the display device 201 in the developing chamber 101

The display device 201 is a display device suitable for a TFT-LCD (thin film transistor liquid crystal display) or an OLED (organic light emitting diode).

The spraying member 104 is disposed on an inner surface of a top portion or a side wall of the developing chamber 101, and the spraying member 104 is connected with a developing agent delivering pipe, which is configured to deliver the developing agent to supply the spraying member 104. The developing agent delivering pipe is connected with a developing agent supply tank, and/or the developing agent delivering pipe is connected with a developing agent recycle member disposed in the development chamber 101. The developing agent recycle member is configured to recycle the developing agent sprayed out of the display device 201 and/or flowing out of the display device 201, and the developing agent recycle member is further configured to deliver the recycled developing agent to the spray member 104.

At least a portion of the conveyor table 102 is disposed in the developing chamber 101, and the conveyor table 102 is configured to move the display device 201 waiting to be processed by the developing process from outside of the developing chamber 101 to inside of the developing chamber 101, and configured to move the display device 201 being processed by the developing process from inside of the developing chamber 101 to outside of the developing chamber 101.

Specifically, the conveyor table 102 is configured to move the display device 201 waiting to be processed by the developing process from outside of the developing chamber 101 to inside of the developing chamber 101 at a constant speed, or configured to move the display device 201 being processed by the developing process from inside of the developing chamber 101 to outside of the developing chamber 101 at a changeable speed (including a situation of accelerating from a stationary to a first speed during a first predetermined time or a situation of accelerating from a third speed to a fourth speed during a second predetermined time).

The air ejection member 103 is disposed in the developing chamber 101. Specifically, the air ejection member 103 is disposed at an entrance of the developing chamber 101, and the air ejection member 103 is fixed on the inner surface of the top portion or the side wall of the developing chamber 101.

The air ejection member 103 is configured to eject airflow onto the display device 201 when the display device 201 is moved from outside of the developing chamber 101 to inside of the developing chamber 101, so as to prevent the developing agent disposed on a portion of the display device 201 within the developing chamber from flowing out of the developing chamber. That is, the air ejection member 103 is configured to intercept the developing agent by the airflow from the portion of the display device 201 inside of the developing chamber 101 flowing toward the portion of the display device 201 outside of the developing chamber 101. On the one hand, it is advantageous that the developing agent can be fully used, and on the other hand, it is advantageous to prevent that the developing agent with high concentration of photoresist remaining in the outside of the developing chamber 101 is evaporated to produce a photoresist residue to affect quality of other display device.

Furthermore, the developing agent is intercepted by the airflow, and the intercepting force applied to the developing agent is non-contact type, so that it is advantageous that amount of the developing agent on display device 201 will not be reduced by a direct contact.

An ejection direction of the airflow ejected by the air ejection member 103 is perpendicular to the surface of the display device 201, or the ejection direction has a first predetermined angle with the surface of the display device 201. That is, the ejection direction is inclined from the direction perpendicular to the surface of the display device 201 toward the moving direction of the display device 201.

Similarly, the spraying direction of the developing agent from the spraying member 104 is perpendicular to the surface of the display device 201, or the spraying direction has a second predetermined angle with the surface of the display device 201. That is, the spraying direction is inclined from the direction perpendicular to the surface of the display device 201 toward the moving direction of the display device 201 or a reverse direction thereof.

In this embodiment, the air ejection member 103 includes a first pipe 1031 and a nozzle 1032, and the first pipe 1031 is connected with the nozzle 1032. The first pipe 1031 is configured to transport the airflow and output the air flow through the nozzle 1032.

The nozzle 1032 includes a valve for controlling the nozzle 1032 opened or closed, and for controlling a flow rate of the air flow ejected from the nozzle 1032.

Refer to FIG. 2, which is a schematic view of a second embodiment of the developing device of the present disclosure. This embodiment is similar to the first embodiment described above, but differences therebetween are that:

In this embodiment, the air ejection member further includes a second pipe 1033 and a third pipe 1034, and the second pipe 1033 and the third pipe 1034 are both connected to the nozzle 1032, wherein the second pipe 1033 is configured to deliver water, and to output the water through the nozzle 1032, and the third pipe 1034 is configured to deliver a cleaning liquid, and to output the cleaning liquid through the nozzle 1032.

Wherein the water is pure water.

The second pipe 1033 and the third pipe 1034 are configured to mix the water delivered by the second pipe 1033 with the cleaning liquid delivered by the third pipe 1034, so as to clean the first pipe 1031 and/or the nozzle 1032. The water delivered by the second pipe 1033 and the cleaning liquid delivered by the third pipe 1034 are configured to prevent the first pipe 1031 and/or the nozzle 1032 being blocked.

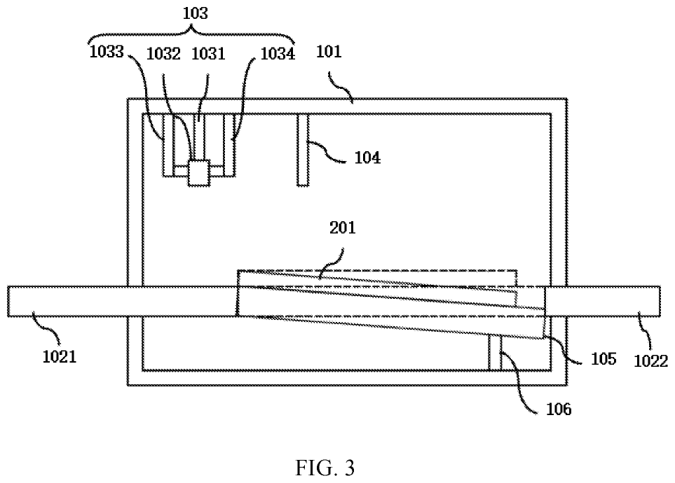

Refer to FIG. 3, which is a schematic view of a third embodiment of the developing device of the present disclosure. This embodiment is similar to the first embodiment or the second embodiment described above, but differences therebetween are that:

In this embodiment, the developing device further includes a lifter, and the conveyor table 102 at least includes a first sub-table 1021 and a second sub-table 1022. The first sub-table 1021 is configured to independently move the display device 201 placed on a surface of the first sub-table 1021, and the second sub-table 1022 is configured to independently move the display device 201 on the surface of the machine the second sub-table 1022. The first sub-table 1021 and the second sub-table 1022 are jointed to form the conveyor table 102 configured to continuously move the display device 201.

The lifter is disposed between the first sub-table 1021 and the second sub-table 1022.

The lifter is configured to control at least one portion of the display device 201 up or down, so that the developing agent disposed on the display device 201 flows toward a predetermined direction.

The first sub-table 1021 of the conveyor table 102 is also configured to move the display device 201 to the lifter.

The lifter includes a movable plate 105 and a lifting column 106, wherein a first side of the movable plate 105 is hinged with the first sub-table 1021, and a second side of the movable plate 105 is connected with the lifting column 106. The lifting column 106 is configured to control the second side of the movable panel 105 up or down, so as to control at least a portion of the display device 201 moved on the lifter (the movable panel 105) up or down, so that the developing agent disposed on the display device 201 flows toward the predetermined direction. It is advantageous that the developing agent fully reacts with the photoresist on the display device 201.

The lifter is configured to control the display device 201 being inclined at the predetermined angle toward the delivering direction of the conveyor table 102, so that the developing agent disposed on the display device 201 flows toward the predetermined direction. Specifically, the lifting column 106 is configured to control the second side of the movable panel 105 up or down, so as to control the display device 201 moved to the lifter (the movable plate 105) being inclined at the predetermined angle toward the delivering direction of the conveyor table 102, so that the developing agent disposed on the display device 201 flows toward the predetermined direction.

The predetermined angle ranges from 1 to 20 degrees. For example, the predetermined angle can be 1 degree, 1.3 degrees, 1.5 degrees, 1.8 degrees, 2 degrees, 2.3 degrees, 2.5 degrees, 2.8 degrees, 3 degrees, 3.3 degrees, 3.5 degrees, 3.8 degrees, 4 degrees, 4.3 degrees, 4.5 degrees, 4.8 degrees, 5 degrees, 5.3 degrees, 5.5 degrees, 5.8 degrees, 6 degrees, 6.3 degrees, 6.5 degrees, 6.8 degrees, 7 degrees, 7.3 degrees, 7.5 degrees, 7.8 degrees, 8 degrees, 8.3 degrees, 8.5 degrees, 8.8 degrees, 9 degrees, 9.3 degrees, 9.5 degrees, 9.8 degrees, 10 degrees, 10.3 degrees, 10.5 degrees, 10.8 degrees, 11 degrees, 11.3 degrees, 11.5 degrees, 11.8 degrees, 12 degrees, 12.3 degrees, 12.5 degrees, 12.8 degrees, 13 degrees, 13.3 degrees, 13.5 degrees, 13.8 degrees, 14 degrees, 14.3 degrees, 14.5 degrees, 14.8 degrees, 15 degrees, 15.3 degrees, 15.5 degrees, 15.8 degrees, 16 degrees, 16.3 degrees, 16.5 degrees, 16.8 degrees, 17 degree, 17.3 degrees, 17.5 degrees, 17.8 degrees, 18 degrees, 18.3 degrees, 18.5 degrees, 18.8 degrees, 19 degrees, 19.3 degrees, 19.5 degrees, 19.8 degrees, and 20 degrees.

Preferably, the predetermined angle ranges from 1 to 5 degrees, in particular the predetermined angle is 5 degrees.

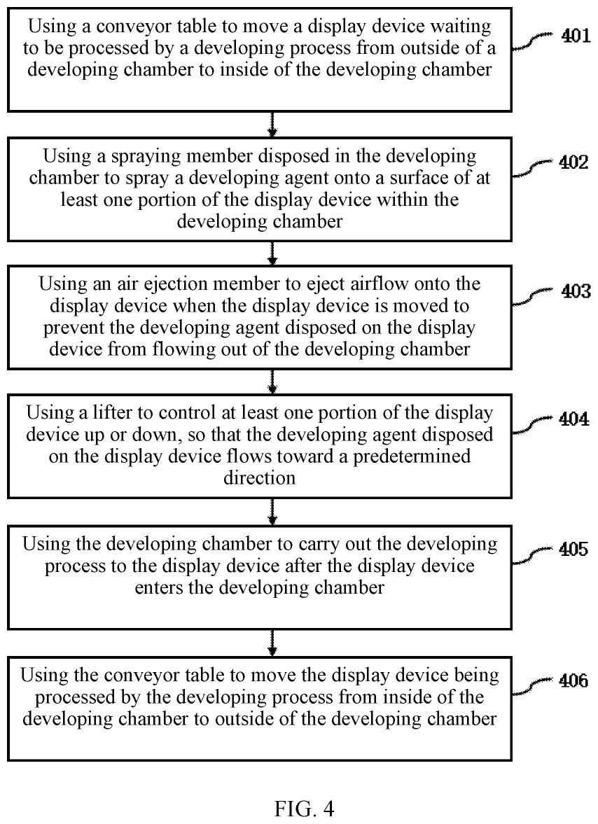

Refer to FIG. 4, which is a flow chart of the developing method of the present disclosure.

A developing method of the present disclosure comprises the following steps:

Step A (401): using a conveyor table 102 to move a display device 201 waiting to be processed by a developing process from outside of a developing chamber 101 to inside of the developing chamber 101. Specifically, the conveyor table 102 moves the display device 201 waiting to be processed by the developing process from outside of the developing chamber 101 to inside of the developing chamber 101 at a constant speed, or moves the display device 201 being processed by the developing process from inside of the developing chamber 101 to outside of the developing chamber 101 at a changeable speed (including a situation of accelerating from a stationary to a first speed during a first predetermined time or a situation of accelerating from a third speed to a fourth speed during a second predetermined time).

The conveyor table 102 at least includes a first sub-table 1021 and a second sub-table 1022. The first sub-table 1021 is configured to independently move the display device 201 placed on a surface of the first sub-table 1021, and the second sub-table 1022 is configured to independently move the display device 201 on the surface of the machine the second sub-table 1022. The first sub-table 1021 and the second sub-table 1022 are jointed to form the conveyor table 102 configured to continuously move the display device 201.

Step B (402): using a spraying member 104 disposed in the developing chamber 101 to spray a developing agent onto a surface of at least one portion of the display device 201 within the developing chamber 101. The spraying member 104 is disposed on an inner surface of a top portion or a side wall of the developing chamber 101, and the spraying member 104 is connected with a developing agent delivering pipe.

The spraying direction of the developing agent from the spraying member 104 is perpendicular to the surface of the display device 201, or the spraying direction has a second predetermined angle with the surface of the display device 201. That is, the spraying direction is inclined from the direction perpendicular to the surface of the display device 201 toward the moving direction of the display device 201 or a reverse direction thereof.

Step C (403): using an air ejection member 103 to eject airflow onto the display device 201 when the display device 201 is moved from outside of the developing chamber 101 to inside of the developing chamber 101, so as to prevent the developing agent disposed on the portion of the display device 201 within the developing chamber 101 from flowing out of the developing chamber 101. The air ejection member 103 is disposed at an entrance of the developing chamber 101, and the air ejection member 103 is fixed on the inner surface of the top portion or the side wall of the developing chamber 101.

The air ejection member 103 intercepts the developing agent by the airflow from the portion of the display device 201 inside of the developing chamber 101 flowing toward the portion of the display device 201 outside of the developing chamber 101. On one hand, it is advantageous that the developing agent can be fully used, and on the other hand, it is advantageous to prevent that the developing agent with high concentration of photoresist remaining in the outside of the developing chamber 101 is evaporated to produce a photoresist residue to affect quality of other display device.

Furthermore, the developing agent is intercepted by the airflow, and the intercepting force applied to the developing agent is non-contact type, so that it is advantageous that amount of the developing agent on display device 201 will not be reduced by a direct contact.

An ejection direction of the airflow ejected by the air ejection member 103 is perpendicular to the surface of the display device 201, or the ejection direction has a first predetermined angle with the surface of the display device 201. That is, the ejection direction is inclined from the direction perpendicular to the surface of the display device 201 toward the moving direction of the display device 201.

The air ejection member 103 includes a first pipe 1031 and a nozzle 1032, and the first pipe 1031 is connected with the nozzle 1032.

The developing method further includes the following steps:

The first pipe 1031 transports the airflow and output the air flow through the nozzle 1032.

The nozzle 1032 includes a valve, and the developing method further includes the following steps:

The valve controls the nozzle 1032 opened or closed.

The valve controls a flow rate of the air flow ejected from the nozzle 1032.

Furthermore, the air ejection member further includes a second pipe 1033 and a third pipe 1034, and the second pipe 1033 and the third pipe 1034 are both connected to the nozzle 1032.

The developing method further includes the following steps:

The second pipe 1033 delivers water, and outputs the water through the nozzle 1032, wherein the water is pure water.

The third pipe 1034 delivers a cleaning liquid, and outputs the cleaning liquid through the nozzle 1032.

The second pipe 1033 and the third pipe 1034 mix the water delivered by the second pipe 1033 with the cleaning liquid delivered by the third pipe 1034, so as to clean the first pipe 1031 and/or the nozzle 1032. The water delivered by the second pipe 1033 and the cleaning liquid delivered by the third pipe 1034 can prevent the first pipe 1031 and/or the nozzle 1032 being blocked.

Step D (405): using the developing chamber 101 to carry out the developing process to the display device 201 after the display device enters the developing chamber 101.

After the step B, the developing method further comprises the following steps:

Step E (404): using a lifter to control at least one portion of the display device 201 up or down, so that the developing agent disposed on the display device 201 flows toward a predetermined direction

Before the step B, the developing method further comprises the following steps:

The first sub-table 1021 of the conveyor table 102 moves the display device 201 to the lifter.

The lifter includes a movable plate 105 and a lifting column 106, wherein a first side (close to the entrance of the developing chamber 101) of the movable plate 105 is hinged with the first sub-table 1021, and a second side (far away from the entrance of the developing chamber 101) of the movable plate 105 is connected with the lifting column 106.

The step E includes:

The lifting column 106 controls the second side of the movable panel 105 up or down, so as to control at least a portion of the display device 201 moved on the lifter (the movable panel 105) up or down, so that the developing agent disposed on the display device 201 flows toward the predetermined direction. It is advantageous that the developing agent fully reacts with the photoresist on the display device 201.

The step E is: the lifter controls the display device 201 is inclined at a predetermined angle toward a delivering direction of the conveyor table 102, so that the developing agent disposed on the display device 201 flows toward the predetermined direction.

Specifically, the lifting column 106 controls the second side of the movable panel 105 up or down, so as to control the display device 201 moved to the lifter (the movable plate 105) being inclined at the predetermined angle toward the delivering direction of the conveyor table 102, so that the developing agent disposed on the display device 201 flows toward the predetermined direction.

The predetermined angle ranges from 1 to 20 degrees.

The predetermined angle ranges from 1 to 20 degrees. For example, the predetermined angle can be 1 degree, 1.3 degrees, 1.5 degrees, 1.8 degrees, 2 degrees, 2.3 degrees, 2.5 degrees, 2.8 degrees, 3 degrees, 3.3 degrees, 3.5 degrees, 3.8 degrees, 4 degrees, 4.3 degrees, 4.5 degrees, 4.8 degrees, 5 degrees, 5.3 degrees, 5.5 degrees, 5.8 degrees, 6 degrees, 6.3 degrees, 6.5 degrees, 6.8 degrees, 7 degrees, 7.3 degrees, 7.5 degrees, 7.8 degrees, 8 degrees, 8.3 degrees, 8.5 degrees, 8.8 degrees, 9 degrees, 9.3 degrees, 9.5 degrees, 9.8 degrees, 10 degrees, 10.3 degrees, 10.5 degrees, 10.8 degrees, 11 degrees, 11.3 degrees, 11.5 degrees, 11.8 degrees, 12 degrees, 12.3 degrees, 12.5 degrees, 12.8 degrees, 13 degrees, 13.3 degrees, 13.5 degrees, 13.8 degrees, 14 degrees, 14.3 degrees, 14.5 degrees, 14.8 degrees, 15 degrees, 15.3 degrees, 15.5 degrees, 15.8 degrees, 16 degrees, 16.3 degrees, 16.5 degrees, 16.8 degrees, 17 degree, 17.3 degrees, 17.5 degrees, 17.8 degrees, 18 degrees, 18.3 degrees, 18.5 degrees, 18.8 degrees, 19 degrees, 19.3 degrees, 19.5 degrees, 19.8 degrees, and 20 degrees.

Preferably, the predetermined angle ranges from 1 to 5 degrees, in particular the predetermined angle is 5 degrees.

The method also includes the following steps:

Step F (406): using the conveyor table 102 to move the display device 201 being processed by the developing process from inside of the developing chamber 101 to outside of the developing chamber 101.

Before the step B, the developing method further comprises the following steps:

Step G: using a developing agent delivering pipe to deliver the developing agent, so as to supply the developing agent to the spraying member 104.

The developing agent delivering pipe is connected with a developing agent supply tank and/or a developing agent recycle member disposed in the development chamber 101.

The developing method further includes the following steps:

The developing agent recycle member recycles the developing agent sprayed out of the display device 201 and/or flowing out of the display device 201, and delivers the recycled developing agent to the spray member 104.

In the present disclosure, the air ejection member 103 intercepts the developing agent by the airflow from the portion of the display device 201 inside of the developing chamber 101 flowing toward the portion of the display device 201 outside of the developing chamber 101, so that the present disclosure can prevent that the developing agent from flowing out of the developing chamber.

As mentioned above, although the above disclosed embodiments of the present disclosure in a preferred, but the above-described preferred embodiments are not intended to limit the present disclosure, those of ordinary skill in the art, without departing from the spirit and scope of the present disclosure, can make various kinds of alterations and modifications, and the scope of the present disclosure defined by the claims in the scope of equivalents.

What is claimed is:

1. A developing device, comprising:
a developing chamber configured to carry out a developing process to a display device therein, wherein a spraying member is disposed in the developing chamber, and is configured to spray a developing agent onto a surface of at least one portion of the display device in the developing chamber;
a conveyor table, wherein at least one portion of the conveyor table is disposed inside the developing chamber, and the conveyor table is configured to move the display device waiting to be processed by the developing process from outside of the developing chamber to inside of the developing chamber, and configured to move the display device being processed by the developing process from inside of the developing chamber to outside of the developing chamber; and
an air ejection member configured to eject airflow onto the display device when the display device is moved from outside of the developing chamber to inside of the developing chamber, so as to prevent the developing agent disposed on a portion of the display device within the developing chamber from flowing out of the developing chamber;
wherein the conveyor table at least comprises a first sub-table and a second sub-table;
wherein the developing device further comprises a lifter disposed between the first sub-table and the second sub-table;
wherein the lifter comprises a movable plate and a lifting column, wherein a first side of the movable plate is hinged with the first sub-table, and a second side of the movable plate is connected with the lifting column;
wherein the spraying member is disposed on an inner surface of a top portion or a side wall of the developing chamber; the spraying member is connected with a developing agent delivering pipe, and the developing agent delivering pipe is connected with a developing agent supply tank and/or a developing agent recycle member disposed in the development chamber; and
wherein the air ejection member is disposed inside of the developing chamber, and an ejection direction of the airflow ejected by the air ejection member is perpendicular to the surface of the display device.

2. The developing device according to claim 1, wherein the air ejection member is disposed at an entrance of the developing chamber, and the air ejection member is fixed on the inner surface of the top portion or the side wall of the developing chamber.

3. A developing device, comprising:
a developing chamber configured to carry out a developing process to a display device therein, wherein a spraying member is disposed in the developing chamber, and is configured to spray a developing agent onto a surface of at least one portion of the display device in the developing chamber;
a conveyor table, wherein at least one portion of the conveyor table is disposed inside the developing chamber, and the conveyor table is configured to move the display device waiting to be processed by the developing process from outside of the developing chamber to inside of the developing chamber, and configured to move the display device being processed by the developing process from inside of the developing chamber to outside of the developing chamber; and
an air ejection member configured to eject airflow onto the display device when the display device is moved from outside of the developing chamber to inside of the developing chamber, so as to prevent the developing agent disposed on a portion of the display device within the developing chamber from flowing out of the developing chamber.

4. The developing device according to claim 3, wherein the air ejection member comprises a first pipe and a nozzle; the first pipe is connected with the nozzle; and the first pipe is configured to move the airflow, and to output the airflow through the nozzle.

5. The developing device according to claim 4, wherein the air ejection member further comprises a second pipe and a third pipe; the second pipe and the third pipe are both connected with the nozzle; the second pipe is configured to deliver water, and to output the water through the nozzle; and the third pipe is configured to deliver a cleaning liquid, and to output the cleaning liquid through the nozzle.

6. The developing device according to claim 3, wherein the developing device further comprises:
a lifter configured to control at least one portion of the display device up or down, so that the developing agent disposed on the display device flows toward a predetermined direction.

7. The developing device according to claim 6, wherein the lifter is configured to control the display device being inclined at a predetermined angle toward a delivering direction of the conveyor table, so that the developing agent disposed on the display device flows toward the predetermined direction; and
the predetermined angle ranges from 1 to 20 degrees.

8. The developing device according to claim 6, wherein the conveyor table at least comprises a first sub-table and a second sub-table;
the lifter is disposed between the first sub-table and the second sub-table; and
the lifter comprises a movable plate and a lifting column, wherein a first side of the movable plate is hinged with the first sub-table, and a second side of the movable plate is connected with the lifting column.

9. The developing device according to claim 3, wherein the air ejection member is disposed inside of the developing chamber.

10. The developing device according to claim 9, wherein the air ejection member is disposed at an entrance of the developing chamber, and the air ejection member is fixed on an inner surface of a top portion or a side wall of the developing chamber.

11. The developing device according to claim 3, wherein an ejection direction of the airflow ejected by the air ejection member is perpendicular to the surface of the display device, or the ejection direction has a first predetermined angle with the surface of the display device.

12. The developing device according to claim 3, wherein the spraying member is disposed on an inner surface of a top portion or a side wall of the developing chamber; the spraying member is connected with a developing agent delivering pipe, and the developing agent delivering pipe is connected with a developing agent supply tank and/or a developing agent recycle member disposed in the development chamber.

13. A developing method, comprising:
a step A of using a conveyor table to move a display device waiting to be processed by a developing process from outside of a developing chamber to inside of the developing chamber;
a step B of using a spraying member disposed in the developing chamber to spray a developing agent onto a surface of at least one portion of the display device within the developing chamber;
a step C of using an air ejection member to eject airflow onto the display device when the display device is moved from outside of the developing chamber to inside of the developing chamber, so as to prevent the developing agent disposed on the portion of the display device within the developing chamber from flowing out of the developing chamber; and
a step D of using the developing chamber to carry out the developing process to the display device after the display device enters the developing chamber.

14. The developing method according to claim 13, wherein after the step B, the method further comprises:
a step E of using a lifter to control at least one portion of the display device up or down, so that the developing agent disposed on the display device flows toward a predetermined direction.

15. The developing method according to claim 14, wherein in the step E, the lifter controls the display device is inclined at a predetermined angle toward a delivering direction of the conveyor table, so that the developing agent disposed on the display device flows toward the predetermined direction; and
the predetermined angle ranges from 1 to 20 degrees.

16. The developing method according to claim 15, wherein the conveyor table at least comprises a first sub-table and a second sub-table; and
the lifter comprises a movable plate and a lifting column, wherein a first side of the movable plate is hinged with the first sub-table, and a second side of the movable plate is connected with the lifting column; and
wherein the step E comprises:
using the lifting column to control the second side of the movable plate up or down, so as to control the display device moved on the lifter being inclined at the predetermined angle toward the delivering direction of the conveyor table, so that the developing agent disposed on the display device flows toward the predetermined direction.

17. The developing method according to claim 13, wherein the method further comprises:
a step F of using the conveyor table to move the display device being processed by the developing process from inside of the developing chamber to outside of the developing chamber.

18. The developing method according to claim 13, wherein an ejection direction of the airflow ejected by the air ejection member is perpendicular to the surface of the display device, or the ejection direction has a first predetermined angle with the surface of the display device.

19. The developing method according to claim 13, wherein before the step B, the developing method further comprises:
a step G of using a developing agent delivering pipe to deliver the developing agent, so as to supply the developing agent to the spraying member;
wherein the developing agent delivering pipe is connected with a developing agent supply tank and/or a developing agent recycle member disposed in the development chamber.

20. The developing method according to claim 13, wherein the step A comprises:
using the conveyor table to move the display device waiting to be processed by the developing process from outside of the developing chamber to inside of the developing chamber at a constant speed, or to move the display device waiting to be processed by the developing process from outside of the developing chamber to inside of the developing chamber at a changeable speed.
